(19) United States
(12) Patent Application Publication
(10) Pub. No.: US 2026/0255478 A1
(43) Pub. Date: Aug. 27, 2026

(54) INTERCONNECT SUBSTRATE AND METHOD OF MAKING THE SAME

(71) Applicant: SHINKO ELECTRIC INDUSTRIES CO., LTD., Nagano (JP)

(72) Inventors: Risa KARASAWA, Nagano (JP); Junji SATO, Nagano (JP); Nobutaka AOKI, Nagano (JP)

(21) Appl. No.: 19/545,905

(22) Filed: Feb. 20, 2026

(30) Foreign Application Priority Data
Feb. 26, 2025 (JP) 2025-029317

(51) Int. Cl. H05K 1/03; H05K 1/185; H05K 3/46

(52) U.S. Cl. CPC H05K 1/0366; H05K 1/185; H05K 3/4644; H05K 2201/0145; H05K 2201/0154; H05K 2201/0275; H05K 2201/09036

(57) ABSTRACT

An interconnect substrate includes a core layer containing fiber bundles including a plurality of fibers, a cavity extending through the core layer, an electronic component disposed in the cavity, and an insulating layer covering the electronic component in the cavity, wherein the fibers protrude from an inner wall surface of the cavity, and the insulating layer is introduced into spaces between the fibers in the cavity.

### CROSS-REFERENCE TO RELATED APPLICATIONS

The present application is based on and claims priority to Japanese Patent Application No. 2025-029317 filed on Feb. 26, 2025, with the Japanese Patent Office, the entire contents of which are incorporated herein by reference.

### FIELD

The disclosures herein generally relate to interconnect substrates and methods of making an interconnect substrate.

### BACKGROUND

An interconnect substrate as known in the art may have a core layer provided with a cavity for housing an electronic component. In such an interconnect substrate, the cavity is formed by using, for example, a router. When the cavity is formed by using the router, the inner wall surface of the cavity has a substantially straight shape. The space between the electronic component and the inner wall surface of the cavity is filled with an insulating layer made of resin. However, sufficient adhesion may not be obtained between the inner wall surface of the cavity formed by using the router and the embedded insulating layer.

### Related-Art Document

### Patent Document

[Patent Document 1] Japanese Laid-open Patent Publication No. 2023-155995

### SUMMARY

According to an aspect of the embodiment, an interconnect substrate includes a core layer containing fiber bundles including a plurality of fibers, a cavity extending through the core layer, an electronic component disposed in the cavity, and an insulating layer covering the electronic component in the cavity, wherein the fibers protrude from an inner wall surface of the cavity, and the insulating layer is introduced into spaces between the fibers in the cavity.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating an example of an interconnect substrate according to a first embodiment;

FIGS. 2A and 2B are partially enlarged views of the cavity and its vicinity illustrated in FIG. 1;

FIGS. 3A and 3B are drawings illustrating an example of a manufacturing process of the interconnect substrate according to the first embodiment;

FIGS. 4A and 4B are drawings illustrating the example of the manufacturing process of the interconnect substrate according to the first embodiment;

FIGS. 5A and 5B are drawings illustrating the example of the manufacturing process of the interconnect substrate according to the first embodiment;

FIGS. 6A and 6B are drawings illustrating the example of the manufacturing process of the interconnect substrate according to the first embodiment;

FIGS. 7A and 7B are drawings illustrating the example of the manufacturing process of the interconnect substrate according to the first embodiment; and

FIGS. 8A through 8D are drawings illustrating the example of the manufacturing process of the interconnect substrate according to the first embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### First Embodiment

### Structure of Interconnect Substrate

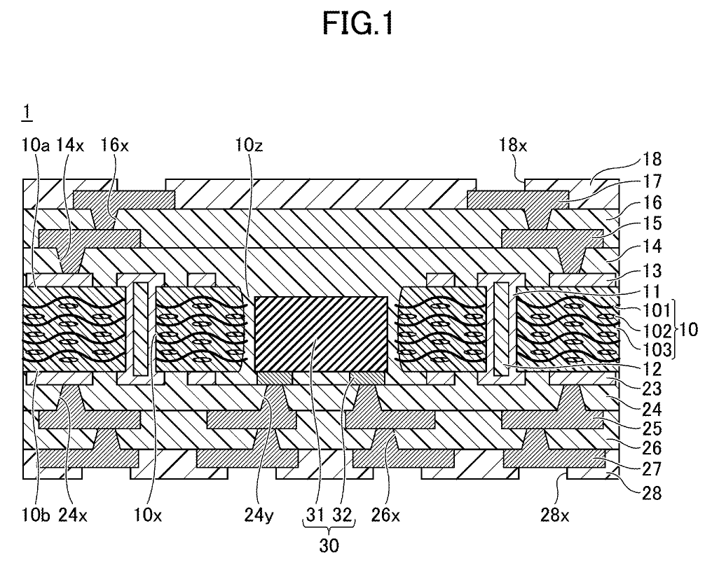

FIG. 1 is a cross-sectional view illustrating an example of an interconnect substrate according to a first embodiment. Referring to FIG. 1, an interconnect substrate 1 is configured such that interconnect layers and insulating layers are laminated on both surfaces of a core layer 10.

Specifically, the interconnect substrate 1 includes an interconnect layer 13, an insulating layer 14, an interconnect layer 15, an insulating layer 16, an interconnect layer 17, and a solder resist layer 18 sequentially laminated on the upper surface 10a of the core layer 10. On the lower surface 10b of the core layer 10, an interconnect layer 23, an insulating layer 24, an interconnect layer 25, an insulating layer 26, an interconnect layer 27, and a solder resist layer 28 are sequentially laminated. The numbers of interconnect layers and insulating layers stacked on the upper surface 10a and the lower surface 10b of the core layer 10 are not limited to those of the example illustrated in FIG. 1.

In the first embodiment, for convenience, the solder resist layer 18 side of the interconnect substrate 1 is referred to as an upper side or a first side, and the solder resist layer 28 side is referred to as a lower side or a second side. The surface of a portion oriented in the same direction as the solder resist layer 18 side is referred to as a first surface or an upper surface, and the surface of the portion oriented in the same direction as the solder resist layer 28 side is referred to as a second surface or a lower surface. However, the interconnect substrate 1 may be positioned upside down when used, or may be arranged at any angle. The plan view refers to the view of an object as seen from the direction normal to the upper surface 10a of the core layer 10, and the plan shape refers to the shape of an object as seen from the direction normal to the upper surface 10a of the core layer 10.

The core layer 10 includes fiber bundles 101 and 102 each containing a plurality of fibers, and a resin 103. The fiber bundles 101 and 102 are impregnated with the resin 103. The material of the resin 103 may be, for example, an epoxy resin, a polyimide resin, a polyester resin, or the like. The resin 103 may include a filler such as silica or alumina.

The fiber bundles 101 each extend in a predetermined direction and are arranged side by side at a predetermined pitch. The fiber bundles 102 each extend in a direction intersecting the fiber bundles 101 in plan view and are arranged side by side at a predetermined pitch. The fiber bundles 102 are perpendicular to the fiber bundles 101 in plan view, for example. The fiber bundles 101 and 102 are interlaced in a plain weave pattern, for example. A member in which the fiber bundles are interlaced in a plain weave pattern is sometimes referred to as a cross.

The fiber bundles 101 and 102 are formed by bundling multiple fibers, each about several micrometers wide, for example, to achieve an overall width of about several hundred micrometers, for example. The voids formed between the fiber bundles 101 and 102 are filled with resin 103 without fibers.

The fiber bundles 101 and 102 are typically glass fiber bundles including a plurality of glass fibers. The fiber bundles 101 and 102 may include multiple types of fibers among carbon fibers, polyester fibers, Tetron fibers, nylon fibers, aramid fibers, and the like. The fiber bundles 101 and 102 are not limited to a plain weave, but may be a satin weave, a twill weave, or the like.

The thickness of the core layer 10 is, for example, in the range of approximately 60 to 1600 μm. The core layer 10 has through holes 10x extending through the core layer 10 in the thickness direction. The plan shape of each of the through holes 10x is, for example, circular.

The core layer 10 is formed with a cavity 10z extending through the core layer 10 to provide clearance above the insulating layer 24. In cross-sectional view, the width of the cavity 10z gradually narrows toward the center of the core layer 10 along its thickness, starting at the first-side opening of the core layer 10, and starting at the second-side opening. The inner wall surface of the cavity 10z has, for example, a curved shape such that the center of the core layer 10 in the thickness direction bulges in cross-sectional view. That is, in cross-sectional view, the width of the cavity 10z at the center of the core layer 10 in the thickness direction is smaller than the widths of the openings at the upper surface 10a and the lower surface 10b of the core layer 10. The difference between the widths is, for example, from 20 μm to 40 μm. Although fibers may protrude into the cavity 10z as described later, the protruding portion of the fibers is not included in the measurement of the width of the cavity 10z.

An electronic component 30 is disposed in the cavity 10z. The electronic component 30 includes a core 31 and electrodes 32 formed on an electrode forming surface of the core 31. The electronic component 30 is arranged face-down in the cavity 10z with the electrodes 32 facing toward the insulating layer 24. A gap between the side surface of the electronic component 30 and the inner wall surface of the cavity 10z is, for example, from 50 μm to 300 μm.

The lower surfaces of the electrodes 32 of the electronic component 30 are flush with the lower surface of the interconnect layer 23, for example. The vertical distance from the lower surface of the interconnect layer 23 to the upper surface of the core 31 is smaller than the vertical distance from the lower surface of the interconnect layer 23 to the upper surface 10a of the core layer 10. The lower surface of the core 31 may be positioned further toward the interconnect layer 23 side than the lower surface 10b of the core layer 10.

The electronic component 30 may be a passive component or an active component. The electronic component 30 may be, for example, an IPD (integrated passive device), a semiconductor chip, a capacitor, an inductor, a resistor, or the like. The plan shape of the cavity 10z is, for example, geometrically similar to the plan shape of the electronic component 30, and its size is larger than that of the electronic component 30. The plan shape of the cavity 10z is, for example, rectangular. A plurality of electronic components 30 may be arranged in the cavity 10z.

The interconnect layer 13 is formed on the upper surface 10a of the core layer 10. The interconnect layer 23 is formed on the lower surface 10b of the core layer 10. The interconnect layer 13 and the interconnect layer 23 are electrically connected by through interconnects 11 formed in the through holes 10x. In the illustrated example, a resin body 12 fills the central inner space of each through interconnect 11. The resin body 12 is, for example, cylindrical, and has an upper end protruding into the interconnect layer 13 and a lower end protruding into the interconnect layer 23. The through interconnects 11 may not have the resin bodies 12. In this case, the through holes 10x are each fully filled with the through interconnect 11.

Each of the interconnect layers 13 and 23 is patterned in a predetermined plan shape. The interconnect layers 13 and 23 and the through interconnects 11 may be made of, for example, copper (Cu) or the like. The thicknesses of the interconnect layers 13 and 23 are, for example, in the range of approximately 25 to 45 μm. The interconnect layer 13, the interconnect layer 23, and the through interconnects 11 may be seamlessly formed.

The insulating layer 14 is formed on the upper surface 10a of the core layer 10 and covers the interconnect layer 13. The insulating layer 14 extends into the cavity 10z and covers the electronic component 30 in the cavity 10z. The insulating layer 14 fills the cavity 10z. The insulating layer 14 is in contact with the upper surface and the side surfaces of the electronic component 30. The insulating layer 14 may extend from the inside of the cavity 10z further downward than the lower surface 10b of the core layer 10. The insulating layer 14 may be in contact with the lower surface of the electronic component 30.

The material of the insulating layer 14 may be an insulating resin mainly composed of, for example, an epoxy-based resin or a polyimide-based resin. The thickness of the insulating layer 14 located on the upper surface 10a of the core layer 10 may be, for example, in the range of approximately 30 to 40 μm. The insulating layer 14 may contain a filler such as silica (SiO₂).

Via holes 14x are formed in the insulating layer 14 to extend through the insulating layer 14 and reach the upper surface of the interconnect layer 13. The via holes 14x may each be an inverted truncated conical hole for which the diameter of the opening toward the insulating layer 16 is larger than the diameter of the opening at the upper surface of the interconnect layer 13.

The interconnect layer 15 is formed on the first side of the insulating layer 14. The interconnect layer 15 includes via interconnects filling the via holes 14x and an interconnect pattern formed on the upper surface of the insulating layer 14. The interconnect pattern is electrically connected to the interconnect layer 13 via the via interconnects. The material of the interconnect layer 15 and the thickness of the interconnect pattern may be substantially the same as those of the interconnect layer 13, for example.

The insulating layer 16 is formed on the upper surface of the insulating layer 14 so as to cover the interconnect layer 15. The material and the thickness of the insulating layer 16 may be substantially the same as those of the insulating layer 14, for example. The insulating layer 16 may contain a filler such as silica (SiO₂).

Via holes 16x are formed in the insulating layer 16 to extend through the insulating layer 16 and reach the upper surface of the interconnect layer 15. The via holes 16x may each be an inverted truncated conical hole for which the diameter of the opening toward the solder resist layer 18 is larger than the diameter of the opening at the upper surface of the interconnect layer 15.

The interconnect layer 17 is formed on the first side of the insulating layer 16. The interconnect layer 17 includes via interconnects filling the via holes 16x and an interconnect pattern formed on the upper surface of the insulating layer 16. The interconnect pattern is electrically connected to the interconnect layer 15 through the via interconnects. The material of the interconnect layer 17 and the thickness of the interconnect pattern may be substantially the same as those of the interconnect layer 13, for example.

The solder resist layer 18 is a protective insulating layer located as the outermost layer on the first side of the interconnect substrate 1, and is formed on the upper surface of the insulating layer 16 so as to cover the interconnect layer 17. The solder resist layer 18 may be formed of, for example, photosensitive epoxy-based insulating resin or acrylic-based insulating resin. The thickness of the solder resist layer 18 is, for example, in the range of approximately 15 to 35 μm.

The solder resist layer 18 has openings 18x. The openings 18x penetrate the solder resist layer 18 and expose the upper surface of the interconnect layer 17. The interconnect layer 17 exposed in the openings 18x may be used as pads for electrical connections with an electronic component such as a semiconductor chip, for example.

On the surface of the interconnect layer 17 exposed in each opening 18x, a metal layer may be formed, or an organic coating may be formed by applying an antioxidant treatment such as organic solderability preservative (OSP) treatment. Examples of the metal layer include an Au layer, a Ni/Au layer (a metal layer formed by laminating a Ni layer and an Au layer in this order), a Ni/Pd/Au layer (a metal layer formed by laminating a Ni layer, a Pd layer, and an Au layer in this order), and a Sn layer.

The insulating layer 24 is formed on the lower surface 10b of the core layer 10 and covers the interconnect layer 23. The insulating layer 24 is also in contact with the lower surface of the insulating layer 14 located below the lower surface 10b of the core layer 10. The material and thickness of the insulating layer 24 may be substantially the same as those of the insulating layer 14, for example. The insulating layer 24 may contain a filler such as silica (SiO₂).

Via holes 24x are formed in the insulating layer 24 to extend through the insulating layer 24 and reach the lower surface of the interconnect layer 23. The insulating layer 24 also includes via holes 24y that penetrate the insulating layer 24 to reach the lower surfaces of the electrodes 32 of the electronic component 30. The via holes 24x and 24y may each be a truncated conical hole for which the diameter of the opening toward the insulating layer 26 is larger than the diameter of the opening at the lower surface of the interconnect layer 23 or the lower surface of an electrode 32.

The interconnect layer 25 is formed on the lower surface side of the insulating layer 24. The interconnect layer 25 includes via interconnects filling the via holes 24x, via interconnects filling the via holes 24y, and an interconnect pattern formed on the lower surface of the insulating layer 24. Portions of the interconnect pattern are electrically connected to the interconnect layer 23 through the via interconnects filling the via holes 24x. The remaining portions of the interconnect pattern are electrically connected to the electrodes 32 through the via interconnects filling the via holes 24y. The material of the interconnect layer 25 and the thickness of the interconnect pattern may be substantially the same as those of the interconnect layer 23, for example.

The insulating layer 26 is formed on the lower surface of the insulating layer 24 so as to cover the interconnect layer 25. The material and the thickness of the insulating layer 26 may be, for example, substantially the same as those of the insulating layer 14. The insulating layer 26 may contain a filler such as silica (SiO₂).

Via holes 26x are formed in the insulating layer 26 to extend through the insulating layer 26 and reach the lower surface of the interconnect layer 25. The via holes 26xmay each be a truncated conical hole for which the diameter of the opening toward the solder resist layer 28 is larger than the diameter of the opening at the lower surface of the interconnect layer 25.

The interconnect layer 27 is formed on the second side of the insulating layer 26. The interconnect layer 27 includes via interconnects filling the via holes 26x and an interconnect pattern formed on the lower surface of the insulating layer 26. The interconnect pattern is electrically connected to the interconnect layer 25 through the via interconnects. The material of the interconnect layer 27 and the thickness of the interconnect pattern may be substantially the same as those of the interconnect layer 23, for example.

The solder resist layer 28 is a protective insulating layer located as the outermost layer on the second side of the interconnect substrate 1, and is formed on the lower surface of the insulating layer 26 to cover the interconnect layer 27. The material and the thickness of the solder resist layer 28 may be substantially the same as those of the solder resist layer 18, for example. The solder resist layer 28 has openings 28x, and portions of the lower surface of the interconnect layer 27 are exposed within the openings 28x. The plan shape of each of the openings 28x may be, for example, circular. The interconnect layer 27 exposed in the openings 28x may be used as pads for electrical connections to a mounting substrate such as a motherboard. If necessary, a metal layer of the kind previously described may be formed on the lower surface of the interconnect layer 27 exposed in the openings 28x, or an oxidation prevention treatment such as OSP treatment may be applied.

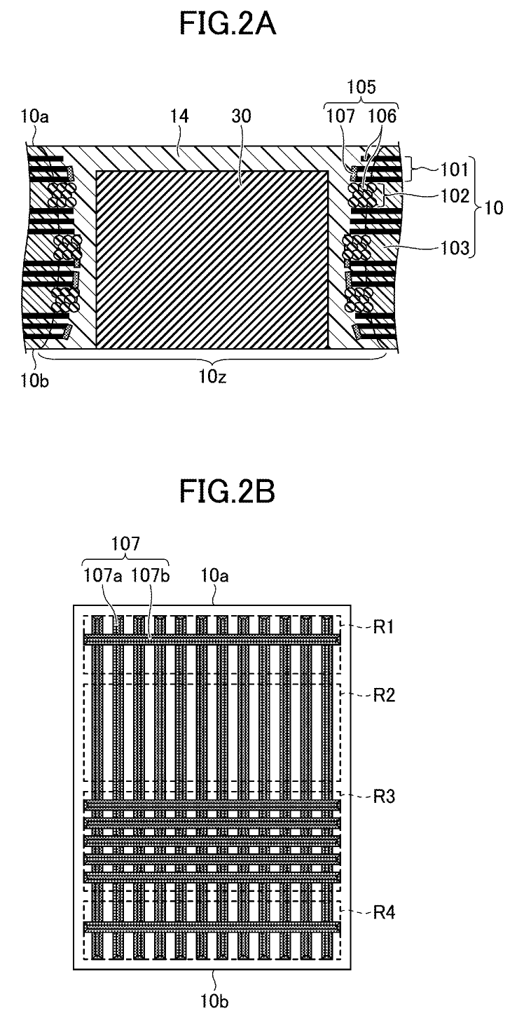

FIGS. 2A and 2B are partially enlarged views of the cavity and its vicinity illustrated in FIG. 1. FIG. 2A is a partial cross-sectional view, and FIG. 2B is a view of fibers projecting from the inner wall surface of the cavity, as seen from the tip side of the fibers. As illustrated in FIG. 2A, each of the fiber bundles 101 and 102 includes a plurality of fibers 105. The plurality of fibers 105 protrude from the inner wall surface of the cavity 10z. Only a part of the plurality of fibers 105 may project from the inner wall surface of the cavity 10z, or all of the plurality of fibers 105 may project from the inner wall surface of the cavity 10z. The insulating layer 14 is introduced or infused into the spaces between adjacent fibers 105 in the cavity 10z.

At least some of the fibers 105 among the fibers 105 projecting from the inner wall surface of the cavity 10z each have a non-melted portion 106 proximate to the core layer 10 and a melted portion 107 closer to the electronic component 30 than the non-melted portion 106. One melted portion 107 may extend across a plurality of non-melted portions 106. The melted portion 107 is formed when a portion of the non-melted portion 106 is melted by heat and then cured. For example, in the case of the fibers 105 being glass fibers, portions of the glass fibers are melted by heat and then cured to become the melted portions 107. The sizes of the melted portions 107 may vary.

As illustrated in FIG. 2B, the melted portions 107 may form a plurality of first melted portions 107a extending in the thickness direction of the core layer 10 and arrayed at a predetermined pitch in a direction perpendicular to the thickness direction of the core layer 10. The pitch of the first melted portions 107a is substantially constant, and is, for example, 10 μm to 70 μm. The melted portions 107 may also form second melted portions 107b bridging the first melted portions 107a.

The interconnect substrate 1 is configured such that the core layer 10 has a plurality of regions arranged along the thickness direction, among which the occupancy ratio of the melted portions 107 varies. For example, in the cavity 10z, the occupancy ratio of the melted portions 107 present in the core layer 10 from the center in the thickness direction to the lower surface 10b is larger than the occupancy ratio of the melted portions 107 present in the core layer 10 from the center in the thickness direction to the upper surface 10a of the core layer 10.

For example, as illustrated in FIG. 2B, the inner wall surface of the cavity 10z is divided into four regions R1 to R4 arranged along the thickness direction of the core layer 10. Here, the widths of the divided regions in the thickness direction of the core layer 10 are such that R1 and R4 each have a width ratio of 1, and R2 and R3 each have a width ratio of 2. In this case, the occupancy ratios of the melted portions 107 in the regions R3 and R4 (i.e., the ratios of the areas covered by the melted portions 107 to the areas of the regions R3 and R4 on the inner wall surface of the cavity 10z) are larger than the occupancy ratios of the melted portions 107 in the regions R1 and R2. In the example illustrated in FIG. 2B, the occupancy ratios of the melted portions 107 in the regions R1 and R4 are substantially the same. Further, the occupancy ratio of the melted portions 107 in the region R2 is smaller than the occupancy ratios of the melted portions 107 in the regions R1 and R4. Moreover, the occupancy ratio of the melted portions 107 in the region R3 is larger than the occupancy ratios of the melted portions 107 in the regions R1 and R4. For example, the occupancy ratios of the melted portions 107 in the regions R1 and R4 are about 60%, the occupancy ratio of the melted portions 107 in the region R2 is about 40%, and the occupancy ratio of the melted portions 107 in the region R3 is about 80%. The occupancy ratio of the melted portions 107 in each region may be derived, for example, by using image processing.

As described above, the interconnect substrate 1 is configured such that the plurality of fibers 105 project from the inner wall surface of the cavity 10z, and the insulating layer 14 is introduced into the spaces between the fibers 105 in the cavity 10z. This structure effectively improves the adhesion between the insulating layer 14 and the inner wall surface of the cavity 10z. Further, improving the adhesion between the insulating layer 14 and the inner wall surface of the cavity 10z effectively suppresses the occurrence of voids in the cavity 10z. Moreover, improving the adhesion between the insulating layer 14 and the inner wall surface of the cavity 10z effectively improves the reliability of the interconnect substrate 1.

Since the insulating layer 14 is introduced into the spaces between the fibers 105 in the cavity 10z, an anchor effect is created, thereby effectively suppressing vertical movement of the electronic component 30 due to mismatch of the thermal expansion coefficients between the insulating layer 14 and the core layer 10. This arrangement effectively reduces the risk of breakage of the connections between the electrodes 32 of the electronic component 30 and the via interconnects in the via holes 24y, and the risk of occurrence of cracks in the insulating layers 14 and 24.

### Method of Making Interconnect Substrate

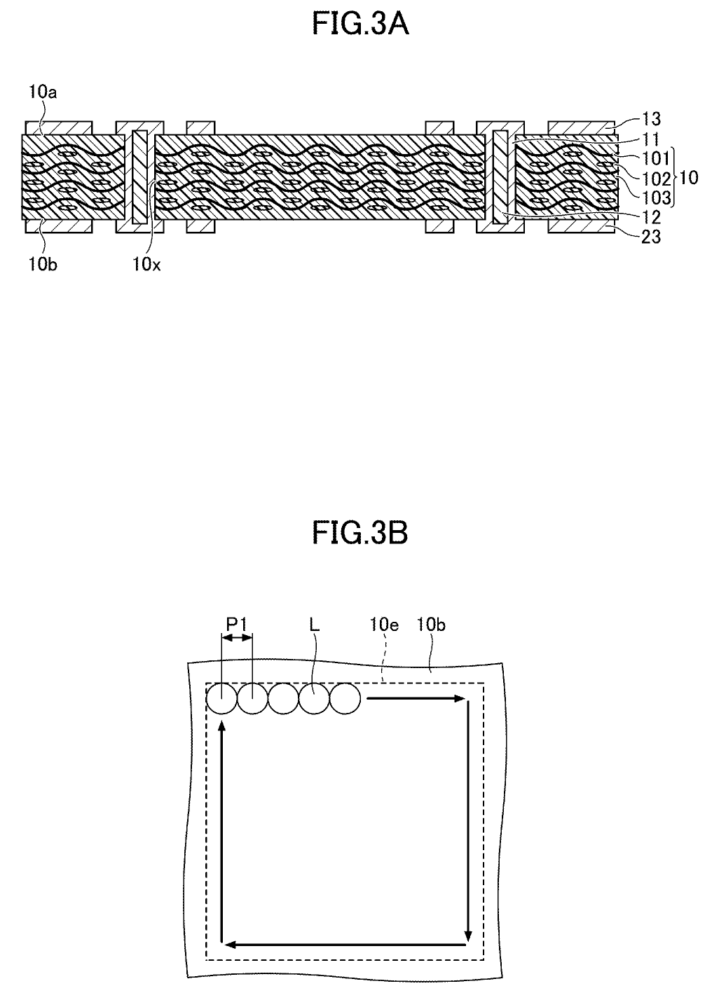

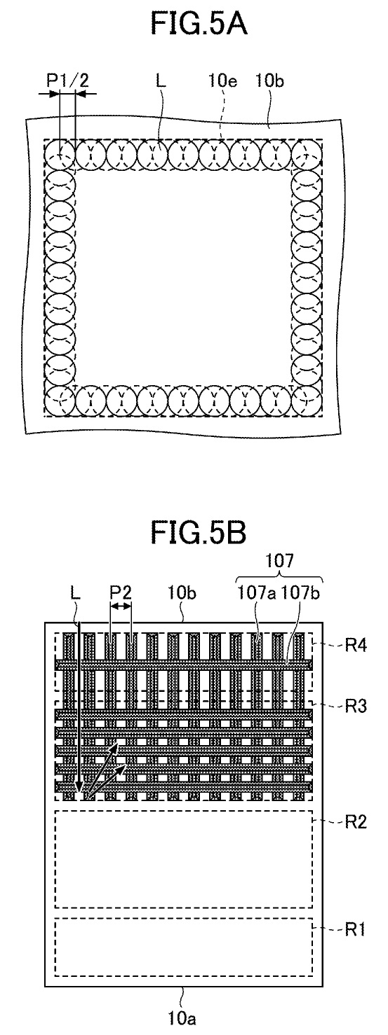

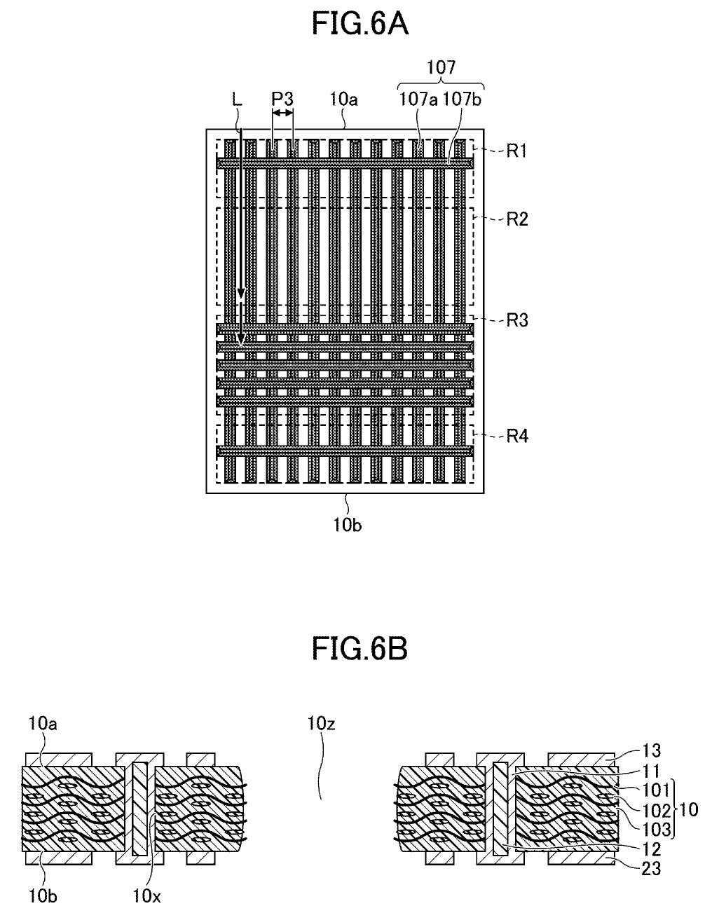

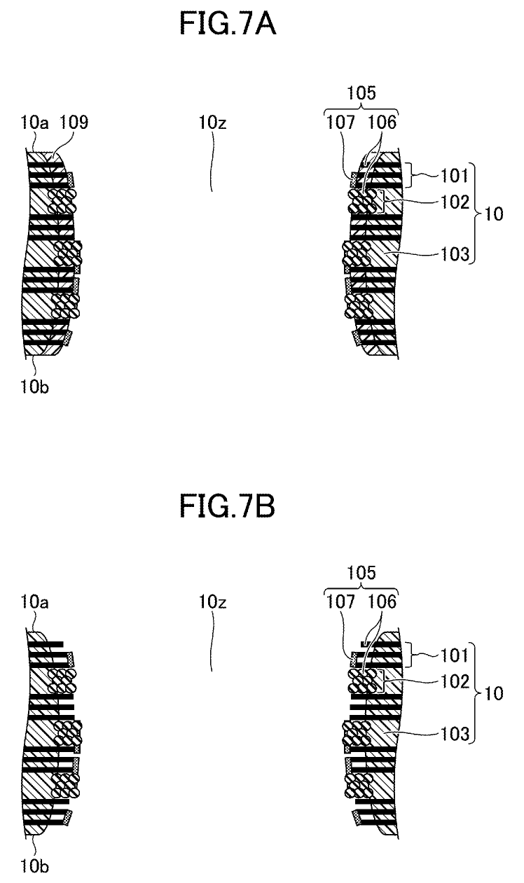

FIGS. 3A and 3B through FIGS. 8A to 8D are drawings illustrating an example of a manufacturing process of the interconnect substrate according to the first embodiment. FIGS. 3A, 6B, and 8A to 8D are cross-sectional views corresponding to FIG. 1. FIGS. 3B, 4A, 4B, and 5A are partial plan views of a region for forming a cavity and its vicinity. FIGS. 5B and 6A are views corresponding to FIG. 2B. FIGS. 5B and 6A illustrate the regions R1 to R4, similarly to FIG. 2B. FIGS. 7A and 7B are cross-sectional views corresponding to FIG. 2A. This example is directed to the process of manufacturing one interconnect substrate. Nonetheless, a plurality of portions to become interconnect substrates may be manufactured, and may then be singulated into individual interconnect substrates.

First, in the step illustrated in FIG. 3A, a core layer 10 including a resin 103 and fiber bundles 101 and 102 each including a plurality of fibers is prepared, and an interconnect layer 13 is formed on the upper surface 10a of the core layer 10, an interconnect layer 23 is formed on the lower surface 10b, and through interconnects 11 and resin bodies 12 are formed in through holes 10x. Specifically, for example, a laminate including the core layer 10 and un-patterned solid copper foils formed on the upper surface 10a and the lower surface 10b is prepared. Then, the through holes 10x penetrating the core layer 10 and the copper foils on both surfaces are formed through the prepared laminate by laser processing using a CO₂ laser, drilling, or the like. If necessary, desmearing is performed to remove residues of the resin of the core layer 10 adhering to the inner surfaces of the through holes 10x.

Next, a seed layer (copper or the like) covering the copper foil on each surface and the inner surfaces of the through holes 10x is formed by, for example, electroless plating or sputtering, and an electroplated layer (copper or the like) is formed on the seed layer by an electroplating method using the seed layer as a current supply path. After this process, through holes remain and are surrounded by the electroplated layer, so that an epoxy resin or the like is injected into these through holes to form the resin bodies 12. This arrangement forms the through interconnects 11 by filling the through holes 10x with the electroplated layer formed on the seed layer, and also forms the resin bodies 12 inside the through interconnects 11. Metal layers made of copper or the like are formed on both end surfaces of the through interconnects 11 and the resin bodies 12 by electroless plating and electroplating. The interconnect layers 13 and 23 are formed on the upper surface 10a and the lower surface 10b of the core layer 10, respectively, each as a laminate of a copper foil, a seed layer, an electroplated layer, and a metal layer. Subsequently, the interconnect layers 13 and 23 are each patterned into a predetermined plan shape by a subtractive method.

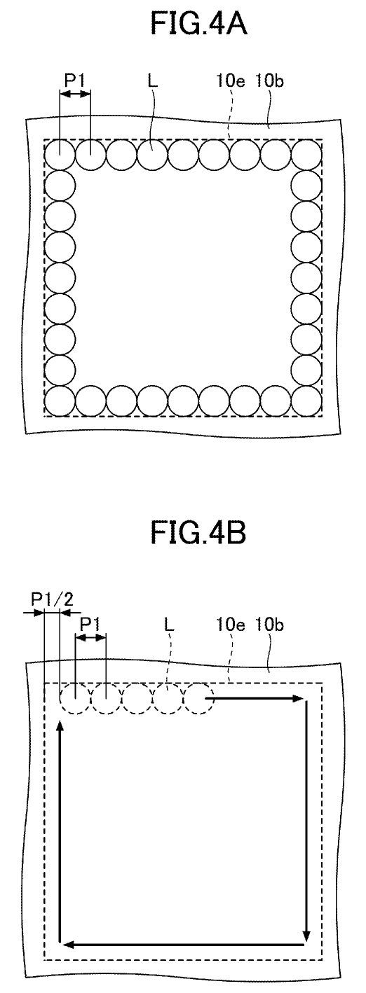

In the steps illustrated in FIGS. 3B through 7A, the core layer 10 is irradiated with a laser beam from both sides to form a cavity 10z penetrating the core layer 10. The cavity 10z may be formed by laser machining using a CO₂ laser. Specifically, as illustrated by solid circles in FIG. 3B, a laser beam L, which is directed onto the lower surface 10b of the core layer 10, is applied successively at a predetermined pitch P1 along the outer edge 10e of a region where the cavity 10z is to be formed. The predetermined pitch P1 may be substantially constant within the range of 20 μm to 140 μm, for example. The laser beam L is applied along a rectangular periphery, for example, as illustrated by the arrows in FIG. 3B, so that a frame-shaped blind hole is formed extending from the lower surface 10b to a depth of approximately half the thickness of the core layer 10. FIG. 4A schematically illustrates positions irradiated with the laser beam along the outer edge 10e. The fibers 105 existing at the positions irradiated with the laser beam are cut.

As illustrated by dashed circles in FIG. 4B, the laser beam L, which is directed onto the lower surface 10b of the core layer 10, is successively applied to positions offset from the irradiated positions in FIG. 4A, at the predetermined pitch P1 along the outer edge 10e of the region where the cavity 10z is to be formed. The illustrated example shows the application of the laser beam L to positions offset by P1/2 from the irradiated positions illustrated in FIG. 4A, but is not a limiting example. The laser beam L is applied along the rectangular periphery, for example, as illustrated by the arrows in FIG. 4B, so that a frame-shaped blind hole is formed extending from the lower surface 10b to a depth of approximately half the thickness of the core layer 10. As in the case of FIG. 3B, the fibers 105 existing at the positions irradiated with the laser beam is cut.

FIG. 5A illustrates the positions irradiated by the laser beam L in FIG. 4A (solid lines) together with the positions irradiated by the laser beam L in FIG. 4B (dashed lines). As a result, the laser beam L is applied at a pitch of P1/2. For example, when the pitch P1 is 20 μm, the laser beam L is seemingly applied at a pitch of 10 μm, which is half of the pitch P1. In the case of the pitch P1 being 140 μm, the laser beam L is seemingly applied at a pitch of 70 μm, which is half the pitch P1.

The solid circles partially overlap the adjacent dashed circles. A particularly large thermal energy is generated at the portions where the adjacent solid circles and dashed circles overlap. By adjusting the energy of the irradiating laser beam and the degree to which the positions of adjacent laser beam irradiations overlap, melted portions 107 are effectively formed by melting the tip regions of the severed fibers 105. For example, the first melted portions 107a, extending in the thickness direction of the core layer 10 from the region R4 to the region R3 as illustrated in FIG. 5B, are effectively formed in the portions where adjacent laser beam irradiations overlap. The first melted portions 107a are arrayed at a pitch P2 in a direction perpendicular to the thickness direction of the core layer 10, for example. The pitch P2 of the first melted portions 107a is substantially constant and approximately P1/2. The wider the pitch P2, the greater the surface irregularity caused by the first melted portions 107a.

In the regions R3 and R4, as illustrated in FIG. 5B, second melted portions 107b bridging the first melted portions 107a are effectively formed. In this state, a blind hole has been formed extending from the lower surface 10b to a depth of approximately half the thickness of the core layer 10. Since no hole has been formed yet in the regions R1 and R2, the laser beam L reaching the bottom of the blind hole is scattered in various directions at the bottom. As a result, in the region R3, the thermal energy of the laser beam reflected at the bottom facilitates forming the second melted portions 107b at various positions. In contrast, the region R4, which is spaced apart from the bottom of the blind hole, receives the laser beam reflected at the bottom at weakened intensities, so that the second melted portions 107b are less likely to be formed by the thermal energy of the laser beam reflected at the bottom. The occupancy ratio of the formed second melted portions 107b is thus larger in the region R3 than in the region R4.

Subsequently, a laser beam L, which is directed onto the upper surface 10a of the core layer 10, is applied successively in a framed-shaped pattern at the predetermined pitch P1 along the outer edge of the region where the cavity 10z is to be formed, at the positions aligned with the solid circles in FIG. 4A, thereby forming a hole communicating with the blind hole extending from the lower surface 10b of the core layer 10. Further, the laser beam L, which is directed onto the upper surface 10a of the core layer 10, is applied successively in the framed-shaped pattern at the predetermined pitch P1 along the outer edge of the region where the cavity 10z is to be formed, at the positions aligned with the dashed circles in FIG. 5A, thereby forming a hole communicating with the blind hole extending from the lower surface 10b of the core layer 10. The energy of the laser beam L directed onto the upper surface 10a may be the same as the energy of the laser beam L directed onto the lower surface 10b. This arrangement removes from the core layer 10 the region where the cavity 10z is to be formed, thereby forming the cavity 10z illustrated in FIGS. 6A and 6B.

As previously described, the tip regions of the severed fibers 105 are melted in the portions where adjacent laser beam irradiations overlap, which effectively forms the first melted portions 107a extending in the thickness direction of the core layer 10 from the region R1 to the region R2 as illustrated in FIG. 6A. The first melted portions 107a are arranged side by side at the pitch P3 in the direction perpendicular to the thickness direction of the core layer 10, for example. The pitch P3 of the first melted portions 107a is substantially constant and approximately P1/2. The first melted portions 107a formed extending from the region R1 to the region R2 are connected to the first melted portions 107a formed extending from the region R3 to the region R4.

Further, as illustrated in FIG. 6A, in the region R1, the tip regions of the severed fibers 105 are melted to form the second melted portions 107b bridging the first melted portions 107a. At this time, the hole is formed from the upper surface 10a of the core layer 10 to a depth of approximately half the thickness, but the other hole has already been formed in the regions R3 and R4. Reflection of the laser beam as described with reference to FIG. 5B thus does not occur. Because of this, the second melted portions 107b are less likely to be formed in the region R2, so that the occupancy ratio of the second melted portions 107b is larger in the region R1 than in the region R2.

As illustrated in FIG. 7A, in the step of forming the cavity 10z, the portion of the resin 103 that is irradiated with the laser beam is carbonized, resulting in the forming of a carbonized portion 109. The carbonized portion 109 is formed, for example, in a frame shape in plan view. At this point, the surface of the carbonized portion 109 constitutes the inner wall surface of the cavity 10z.

In the step illustrated in FIG. 7B, the cavity 10z is desmeared under a predetermined temperature condition to remove the residue of the resin 103 adhering to the inner wall surface of the cavity 10z. The desmearing eliminates the carbonized portion 109 together with the residue of the resin 103, so that portions of the fibers 105 including the non-melted portions 106 and the melted portions 107 protrude from the inner wall surface of the cavity 10z. At this point, the surface of the resin 103 constitutes the inner wall surface of the cavity 10z.

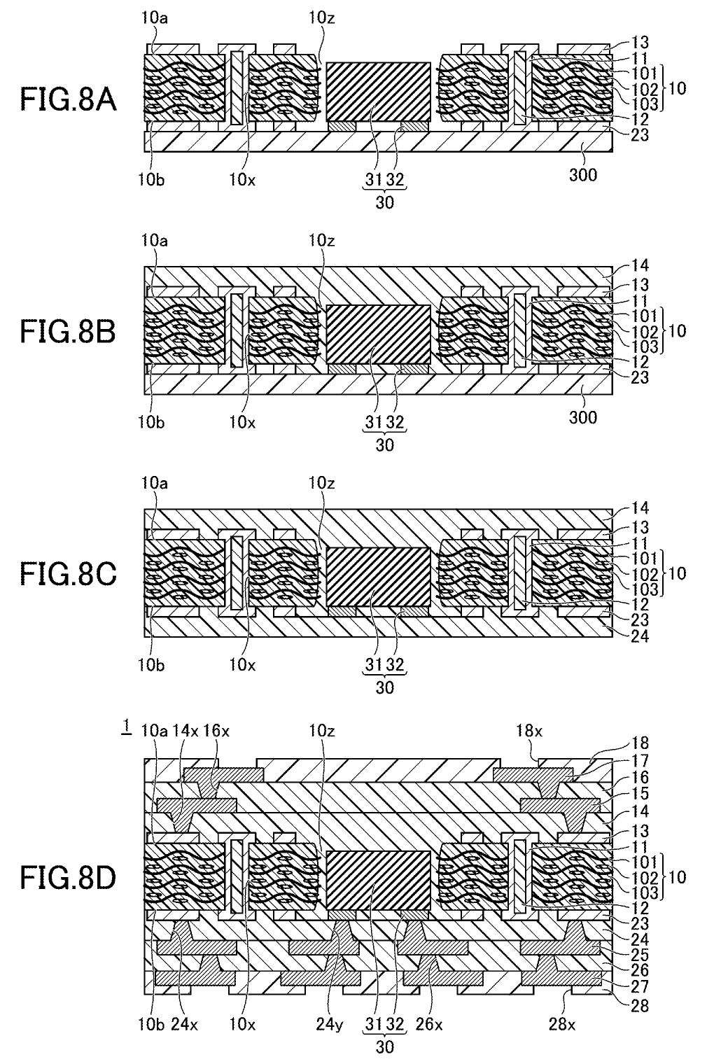

In the step illustrated in FIG. 8A, an electronic component 30 is disposed in the cavity 10z. Specifically, first, a support film 300 is laminated on the lower surface of the interconnect layer 23 so as to close the cavity 10z. The support film 300 may be, for example, a resin film having a weak adhesive force. Next, the electronic component 30 having electrodes 32 is arranged face-down on the upper surface of the support film 300 exposed in the cavity 10z. The electronic component 30 may be arranged using, for example, a mounter for electronic components.

In the step illustrated in FIG. 8B, an insulating layer 14 is formed to cover the electronic component 30 in the cavity 10z and to extend from the inside of the cavity 10z to the upper surface 10a of the core layer 10 to cover the upper surface and the side surfaces of the interconnect layer 13. The insulating layer 14 is introduced into the spaces between the fibers 105. The insulating layer 14 extends downward from the cavity 10z beyond the lower surface 10b of the core layer 10.

Specifically, for example, a semi-cured epoxy-based resin film or the like is laminated on the upper surface 10a of the core layer 10 so as to cover the interconnect layer 13. The epoxy-based resin film or the like is pressed toward the core layer 10 while applying heat by using a vacuum laminator or the like. As a result, the epoxy-based resin film or the like softens and enters the cavity 10z, and is embedded in the cavity 10z so as to cover the electronic component 30. Subsequently, the epoxy-based resin film or the like is cured to form the insulating layer 14. As an alternative to laminating the epoxy-based resin film or the like, an epoxy-based resin or the like in liquid or paste form may be applied and then cured to form the insulating layer 14.

As illustrated in FIG. 6A, the region R2 of the inner wall surface of the cavity 10z has a small occupancy ratio of the melted portions 107. With this arrangement, when the softened resin to form the insulating layer 14 is introduced from the upper surface 10a side of the core layer 10, the flow of the resin is less likely to be obstructed, allowing the resin to be easily injected into the cavity 10z. As a result, the risk of defective injection of the insulating layer 14 is effectively reduced.

Further, there is a risk that the electronic component 30 is displaced by the pressure for injecting the softened resin. Since the cavity 10z has a shape that narrows at the center, the maximum shift amount is effectively suppressed. This arrangement effectively reduces misalignment between the electrodes 32 and the via interconnects in the via holes 24y, thereby improving the connection reliability. Further, even when the electrodes 32 of the electronic component 30 extend from the lower surface of the core 31 to the side surface, for example, the shape of the cavity 10z narrowing at the center effectively reduces the risk of electrical contact and short-circuiting between the electrodes 32 located on the side surface and the interconnect layers 13 and 23.

The insulating layer formed on the upper surface 10a of the core layer 10 and the insulating layer located in the cavity 10z and covering the electronic component 30 may be formed separately. In this case, the insulating layer located in the cavity 10z and covering the electronic component 30 is formed first, and then another insulating layer is formed on the upper surface 10a of the core layer 10.

In the step illustrated in FIG. 8C, the support film 300 is removed, and, then, an insulating layer 24 covering the interconnect layer 23 is formed on the lower surface 10b of the core layer 10. Similarly to the insulating layer 14, the insulating layer 24 may be formed by using an epoxy-based resin film or the like, or an epoxy-based resin in liquid or paste form or the like.

In the step illustrated in FIG. 8D, the remaining layers are sequentially laminated. First, interconnect layers 15 and 25 are formed. Specifically, via holes 14x are formed in the insulating layer 14 so as to penetrate the insulating layer 14 and expose the upper surface of the interconnect layer 13. Further, via holes 24x penetrating the insulating layer 24 and exposing the lower surface of the interconnect layer 23 and via holes 24y penetrating the insulating layer 24 and exposing the lower surfaces of the electrodes 32 of the electronic component 30 are formed in the insulating layer 24. The via holes 14x, 24x, and 24y may be formed, for example, by laser processing using a CO₂ laser or the like. After the via holes 14x, 24x, and 24y are formed, desmearing is preferably performed to remove resin residues adhering to the surfaces of the interconnect layer 13, the interconnect layer 23, and the electrodes 32 exposed at the ends of the via holes 14x, 24x, and 24y, respectively.

Subsequently, the interconnect layer 15 is formed on the first side of the insulating layer 14. The interconnect layer 15 includes via interconnects filling the via holes 14x and an interconnect pattern formed on the upper surface of the insulating layer 14. The interconnect layer 15 is electrically connected to the interconnect layer 13 exposed at the bottom of the via holes 14x.

Further, the interconnect layer 25 is formed on the second side of the insulating layer 24. The interconnect layer 25 includes via interconnects filling the via holes 24x, via interconnects filling the via holes 24y, and an interconnect pattern formed on the lower surface of the insulating layer 24. Portions of the interconnect pattern are electrically connected to the interconnect layer 23 through the via interconnects filling the via holes 24x. The remaining parts of the interconnect pattern are electrically connected to the electrodes 32 through the via interconnects disposed in the via holes 24y.

The interconnect layers 15 and 25 may be formed using any type of interconnect formation method such as a semi-additive method and a subtractive method. For example, in the case of using a semi-additive method to form the interconnect layer 15, a seed layer of copper is formed by electroless plating on the surface of the insulating layer 14 including the inner walls of the via holes 14x and the surfaces of the interconnect layer 13 exposed in the via holes 14x. A plating resist pattern having openings matching the shape of the interconnect pattern constituting the interconnect layer 15 is then formed on the seed layer, followed by depositing an electroplated layer on the seed layer exposed in the openings of the plating resist pattern by electrolytic plating of copper using the seed layer as a current supply path. The plating resist pattern is removed, and then etching is performed using the electroplated layer as a mask to remove the portions of the seed layer not covered by the electroplated layer, thereby effectively fabricating the interconnect layer 15 having the via interconnects and the interconnect pattern. The interconnect layer 25 may be formed by substantially the same method.

Further, an insulating layer 16 is formed on the upper surface of the insulating layer 14 so as to cover the interconnect layer 15. Also, an insulating layer 26 is formed on the lower surface of the insulating layer 24 so as to cover the interconnect layer 25. The insulating layers 16 and 26 may be formed, for example, by substantially the same method as that used for the insulating layer 14. Thereafter, an interconnect layer 17 is formed on the first side of the insulating layer 16, and an interconnect layer 27 is formed on the second side of the insulating layer 26. The interconnect layers 17 and 27 may be formed, for example, by substantially the same method as that used for the interconnect layer 15.

A solder resist layer 18 is formed on the upper surface of the insulating layer 16 so as to cover the interconnect layer 17. Also, a solder resist layer 28 is formed on the lower surface of the insulating layer 26 so as to cover the interconnect layer 27. The solder resist layer 18 may be formed, for example, by applying a photosensitive epoxy-based insulating resin or acrylic-based insulating resin in liquid or paste form to the upper surface of the insulating layer 16 so as to cover the interconnect layer 17 by screen printing, roll coating, spin coating, or the like. Alternatively, a photosensitive epoxy-based insulating resin film or a photosensitive acrylic-based insulating resin film, for example, may be laminated on the upper surface of the insulating layer 16 so as to cover the interconnect layer 17. The method for forming the solder resist layer 28 is substantially the same as that for forming the solder resist layer 18.

Subsequently, the solder resist layers 18 and 28 are exposed and developed (photolithography method). As a result, openings 18x are formed in the solder resist layer 18 so as to expose parts of the upper surface of the interconnect layer 17. Openings 28x are also formed in the solder resist layer 28 so as to expose parts of the lower surface of the interconnect layer 27. The plan shape of each of the openings 18x and 28x may be, for example, circular. The diameter of each of the openings 18x and 28x may be designed as appropriate in accordance with an object to be connected (i.e., semiconductor chip, motherboard, or the like).

In this step, a metal layer of the same kind as previously described may be formed on the upper surface of the interconnect layer 17 exposed at the bottom of the openings 18x and the lower surface of the interconnect layer 27 exposed at the end of the openings 28x by, for example, electroless plating. Alternatively, an anti-oxidation treatment such as OSP treatment may be applied instead of forming the metal layer. By following these steps, the manufacture of the interconnect substrate 1 is achieved.

According to at least one embodiment, adhesion between the inner wall surface of a cavity and the insulating layer covering an electronic component in the cavity may be improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The present disclosures non-exhaustively include the subject matter set out in the following clauses.

Clause 1. A method of making an interconnect substrate, comprising:

forming a cavity penetrating a core layer by directing a laser beam at the core layer from both sides thereof, the core layer containing fiber bundles including a plurality of fibers;

desmearing the cavity;

arranging an electronic component in the cavity; and

forming an insulating layer covering the electronic component in the cavity,

wherein the desmearing of the cavity causes the fibers to protrude from an inner wall surface of the cavity, and

the forming of the insulating layer includes infusing the insulating layer into spaces between the fibers.

Clause 2. The method according to clause 1, wherein the fiber bundles are impregnated with a resin,

wherein the forming of the cavity carbonizes the resin in a portion irradiated with the laser beam, thereby forming a carbonized portion, and the desmearing removes the carbonized portion, thereby causing the fibers to protrude from the inner wall surface of the cavity.

Clause 3. The method according to clause 1, wherein at least some of the fibers protruding from the inner wall surface of the cavity have non-melted portions proximate to the core layer and melted portions closer to the electronic component than the non-melted portions.

Clause 4. The method according to clause 3, wherein the forming of the cavity includes forming the cavity by directing the laser beam at the core layer from a direction of one surface thereof, and then directing the laser beam at the core layer from a direction of another surface thereof, and

wherein in the cavity, an occupancy ratio of the melted portions in a region from the one surface to a center of the core layer in a thickness direction is larger than an occupancy ratio of the melted portions in a region from the another surface to the center.

Clause 5. The method according to clause 1, wherein the forming of the cavity includes directing the laser beam sequentially at first irradiation positions at a predetermined pitch, and directing the laser beam sequentially at positions offset from the first irradiation positions at the predetermined pitch.

What is claimed is:

1. An interconnect substrate comprising:
a core layer containing fiber bundles including a plurality of fibers;
a cavity extending through the core layer;
an electronic component disposed in the cavity; and
an insulating layer covering the electronic component in the cavity,
wherein the fibers protrude from an inner wall surface of the cavity, and
the insulating layer is introduced into spaces between the fibers in the cavity.

2. The interconnect substrate according to claim 1, wherein at least some of the fibers protruding from the inner wall surface of the cavity have non-melted portions proximate to the core layer and melted portions closer to the electronic component than the non-melted portions.

3. The interconnect substrate according to claim 2, wherein the melted portions include first melted portions extending in a thickness direction of the core layer and arranged side by side at a predetermined pitch.

4. The interconnect substrate according to claim 3, wherein the melted portions include second melted portions bridging the first melted portions.

5. The interconnect substrate according to claim 4, wherein the core layer includes a plurality of regions arranged along a thickness direction thereof, among which an occupancy ratio of the melted portions varies.

6. The interconnect substrate according to claim 1, wherein in cross-sectional view, a width of the cavity gradually narrows toward a center of the core layer along a thickness thereof, starting at an opening at one side of the core layer, and starting at an opening at another side of the core layer.

7. The interconnect substrate according to claim 1, wherein the core layer includes an epoxy resin, a polyimide resin, or a polyester resin having a filler therein, the filler being silica or alumina.

8. The interconnect substrate according to claim 1, wherein the fiber bundles are glass fiber bundles.

9. The interconnect substrate according to claim 1, wherein a plan shape of the cavity is geometrically similar to a plan shape of the electronic component, and the cavity is larger than the electronic component in plan view.

10. The interconnect substrate according to claim 1, wherein a gap between a side surface of the electronic component and the inner wall surface of the cavity is from 50 μm to 300 μm.

11. The interconnect substrate according to claim 1, further comprising:
a first interconnect layer disposed on one surface of the core layer;
a second interconnect layer disposed on another surface of the core layer;
a first insulating layer disposed on the one surface of the core layer to cover the first interconnect layer;
a second insulating layer disposed on the another surface of the core layer to cover the second interconnect layer;
a first via extending through the first insulating layer to be electrically connected to the first interconnect layer; and
a second via extending through the second insulating layer to be electrically connected to the second interconnect layer, and
wherein the first via and the second via both have truncated conical shapes and are tapered in opposite directions.

12. The interconnect substrate according to claim 11, wherein a vertical distance from a lower surface of the second interconnect layer to an upper surface of the electronic component is smaller than a vertical distance from the lower surface of the second interconnect layer to an upper surface of the core layer.

13. The interconnect substrate according to claim 11, wherein the electronic component includes an electrode, and a lower surface of the electrode is flush with a lower surface of the second interconnect layer.
